(19) United States
(12) Patent Application Publication
(10) Pub. No.: US 2012/0033384 A1
(43) Pub. Date: Feb. 9, 2012

(54) GRAPHITE WRAPPED HEAT SPREADING PILLOW

(76) Inventor: Unnikrishnan G. PILLAI, Bangalore (IN)

(21) Appl. No.: 12/852,291

(22) Filed: Aug. 6, 2010

(51) Int. Cl. H05K 7/20; F28F 21/02

(52) U.S. Cl. 361/718; 361/704; 165/185

(57) ABSTRACT

A cooling device and method for dissipating heat from a heat-generating component to a surface or object with high heat capacity, thereby reducing the formation of localized temperature buildup, is disclosed. In one embodiment, the cooling device includes a highly conductive and flexible graphite sheet wrapped around a core of flexible material like an elastomer or foam. The pillow thus formed is thereafter placed between the heat-generating component and heat spreading metal surface, such that the two flat wide surfaces of the pillow contact the flat surfaces of those two objects. Due to the high thermal conductivity of the graphite sheet along its surface, the heat transferred from the heat generating component travels along the sheet, curving around the foam sheet and traveling to the opposite side, which is in contact with the heat sinking surface, thus conducting the heat away from the source.

### FIELD OF THE INVENTION

The present invention generally relates to a cooling device. More particularly, the present invention relates to a method and device for protecting heat sensitive features of electronic components from damage during processing.

### BACKGROUND

As electronic products continue to shrink, there is a persistent effort to reduce the size of the integrated circuits (IC) found therein. At reduced architectural dimensions, an IC's heat sensitivity increases because of small feature size and thin wafers that distort easily. Additionally, ICs are now being designed to utilize novel and very thin organic or inorganic dielectrics, which also have limited thermal stability, in some cases well below 200° C. At the same time, the change to lead-free solders in ICs has increased the peak processing temperatures from, for example, about 220° C. for tin-lead solders to 245° C. or even 260° C. for tin-silver-copper solders.

The problem of thermal sensitivity is most pronounced with processor chips, which develop considerable heat during normal operation. In one current practice, these chips are mounted within an IC package using a flip chip format. During high power operation, the heat generated by the flip chip IC is dissipated through the package's solder joints to the main circuit board as well as through the package's lid.

In addition to ICs, other electronic components such as optoelectronic communication devices (e.g., transceivers) and displays (e.g., vacuum fluorescent displays) suffer from similar heat sensitivity during various processing stages. Specifically, optoelectronic communication devices are currently considered stable up to temperatures of about 80° C. to 90° C., while vacuum fluorescent displays must be assembled using selective soldering techniques because of their thermal instability. As with ICs, some method of heat dissipation is required to maintain the integrity of these electronic components during processing and in-service use.

Thermal dissipation devices are commonly used to keep electronic components stable during high temperature, in-service operation. These devices are in thermal communication with the component and generally employ conduction, convection, or a combination thereof to dissipate heat energy. Heat sinks in particular are common thermal dissipation devices for in-service operation. A heat sink is typically a mass of material that is thermally coupled to one of the electronic component's heat-conducting or heat-generating features, e.g., the package lid of an IC, with thermal grease or adhesive. Alternatively, a heat sink may be attached to a heat-conducting feature by bolting the heat sink to the heat-conducting feature. Heat sinks rely on conduction to draw heat energy away from a high-temperature region toward the heat sink. The heat energy is then dissipated from the heat sink's surface to the atmosphere by convection.

A heat sink's thermal efficiency can be increased by forcing convection with an air stream over the surface, usually with a fan, or, in more advanced applications, by using a liquid to absorb heat from the heat sink. However, the efficiency of a heat sink is necessarily limited by the surface area of the heat sink, i.e., its convecting surface area. Further, while heat sinks have been utilized to dissipate heat during in-service operation, they have not been employed to address heat dissipation needs during elevated processing or operating temperatures.

Heat sinks attached by bolting depend on direct contact between the heat sink and the heat generating device, which is not very efficient due to the irregularities on the surfaces of the heat generating device and heat sink. This may alleviated to some extent by using silicone based thermal grease. However, this solution is not suitable when the heat generating device and the heat sink are physically separated due to mechanical constraints.

Heat sinks coupled to a heat generating device by adhesive are more efficient due to the adhesive, which fills the gaps in the interface. However, this method makes rework difficult due to the permanent nature of the adhesive bond. Similar to attaching a heat sink by bolting, this also cannot be applied to cases in which the two surfaces are physically separated due to mechanical constraints.

An alternative to heat sinks include placing thermally conductive and electrically insulating pads between the heat generating device and heat sink. Also, graphite sheets may be used to connect the heat generating device and heat sink.

Placement of thermally conductive and electrically insulating pads improve the transfer of heat since they are flexible to some extent, thereby absorbing some of the irregularities in the interface between the heat generating device and the heat sink. However, in cases where the two surfaces are physically separated by more than a millimeter, these pads are not effective, since their thermal conductivity reduces drastically when the thickness increases.

Graphite sheets are becoming popular as heat exchangers. In case of two surfaces which are physically separated, two ends of a thin graphite sheet which has very high conductivity in the lateral direction, or along it's surface, and very high flexibility can be attached to the heat generating device and heat sink surfaces. This solution will work as long as the surfaces are simultaneously accessible for attaching the graphite sheet. In cases where the surfaces are not simultaneously accessible-such as when the graphite sheet is inside the housing and the lid of the housing, the necessity of assembling the lid necessitates a long graphite sheet. This is expensive and less effective due to reduced thermal conduction caused by the length of the sheet. Moreover, the adhesive strength can wear of with time, thus reducing the effectiveness of the thermal transfer.

### SUMMARY

The present invention relates generally to a cooling device that can help dissipate heat from a heat-generating component to a surface or object with high heat capacity, thereby reducing the formation of localized temperature buildup. In one embodiment, the cooling device includes a highly conductive and flexible graphite sheet wrapped around a core of flexible material like an elastomer or foam. The pillow thus formed is thereafter placed between the heat-generating component and heat spreading metal surface, such that the two flat wide surfaces of the pillow contact the flat surfaces of those two objects. Due to the high thermal conductivity of the graphite sheet along its surface, the heat transferred from the heat generating component travels along the sheet, curving around the foam sheet and traveling to the opposite side, which is in contact with the heat sinking surface, thus conducting the heat away from the source.

In one embodiment, a cooling device includes a cooling device body having a flexible elastomer block surrounded on at least two sides by thermally conductive graphite.

In another embodiment, a method for cooling an electronic component includes bringing a cooling device into thermal communication with the electronic component. The cooling device includes a flexible elastomer block surrounded on at least two sides by thermally conductive graphite.

In yet another embodiment, a heat sink includes a cooling device having a cooling device body including a foam block surrounded on at least two sides by thermally conductive graphite.

Other features and advantages of the present invention will become more readily apparent to those of ordinary skill in the art after reviewing the following detailed description and accompanying drawings.

### BRIEF DESCRIPTION OF THE DRAWINGS

The details of various embodiments present invention, both as to their structure and operation, may be gleaned in part by study of the accompanying drawings, in which like reference numerals refer to like parts, and in which:

FIG. 1 is an example of a cooling device in accordance with embodiments of the present invention.

FIG. 2 is an example of the cooling device of FIG. 1, placed proximate to a heat generating component.

FIG. 3 is another example of a cooling device in accordance with embodiments of the present invention.

FIG. 4 is an example of the cooling device of FIG. 3, placed proximate to a heat generating component.

FIG. 5 is a block diagram illustrating an example wireless communication device that may be used in connection with various embodiments described herein; and

FIG. 6 is a block diagram illustrating an example computer system that may be used in connection with various embodiments described herein.

### DETAILED DESCRIPTION

Certain embodiments as disclosed herein provide for heat dissipation for modern electronic devices. As is appreciated, there are many heat generating components in modern electronic devices and installations such as mobile phones, cameras, PDAs, computers, base stations etc. To maintain reliability and avoid an uncomfortable experience for users in (e.g., overheating of personal devices), the heat can be spread to large metallic surfaces, which will in turn dissipate the heat more uniformly, reducing the build up of hot spots. The invention described herein is an elegant and effective solution for heat dissipation in these applications.

Generally, the heat dissipated device described herein includes a block of flexible material like foam or elastomer over which a highly flexible sheet of graphite is wrapped. The graphite sheet may be attached to the block by some adhesive such as acrylic adhesive applied on the inner side of the graphite sheet. The graphite sheet may also include a layer of adhesive on the outer side of the graphite sheet such as a pressure sensitive acrylic (“PSA”) adhesive to improve the conduction of heat between the surface of the graphite sheet and the mating surfaces.

After reading this description it will become apparent to one skilled in the art how to implement the invention in various alternative embodiments and alternative applications. However, although various embodiments of the present invention are described herein, it is understood that these embodiments are presented by way of example only, and not limitation. As such, this detailed description of various alternative embodiments should not be construed to limit the scope or breadth of the present invention as set forth in the appended claims.

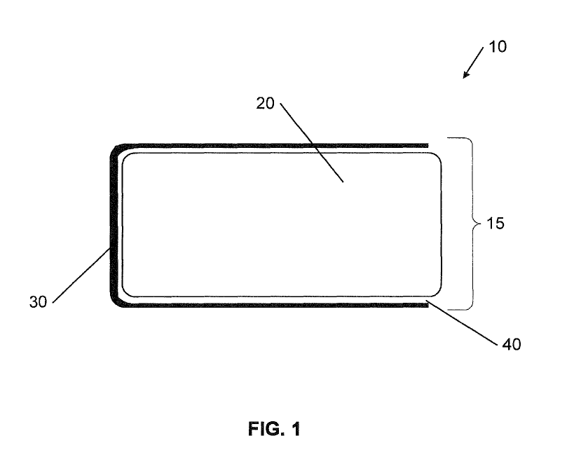

For example, it will be apparent to the person of ordinary skill in the art, given the benefit of this disclosure, that the exemplary electronic components, cooling devices, cooling media, etc., shown in FIGS. 1-6 are not necessarily to scale. Certain dimensions, such as the thickness of the cooling device or cooling medium, may have been enlarged relative to other dimensions, such as the thickness of the heat sensitive component, for clarity of illustration and for a more user-friendly description of the illustrative examples discussed below. It will also be understood by the person of ordinary skill in the art, given the benefit of this disclosure, that the cooling devices disclosed here can be used generally in any orientation relative to gravity and/or other components to which they might be disposed on or be in thermal communication.

In accordance with certain examples, a cooling device comprising a cooling device body is disclosed. The cooling device body is positioned such that it is in thermal communication with a heat sensitive material or heat sensitive component. Such thermal communication can be accomplished using numerous methods including, but not limited to, placing the cooling device body directly onto the heat sensitive material or heat sensitive component, placing the cooling device body a suitable distance from the heat sensitive material or heat sensitive component while maintaining heat transfer between the heat sensitive material or the heat sensitive component, etc. For example, referring to FIG. 1, an exemplary cooling device 10 is shown. Cooling device 10 includes a device body 15 which is formed from a flexible material core 20 (e.g., block, sheet, etc.). As shown in FIG. 1, a graphite layer 30 is attached to flexible material block 20 on three sides.

Flexible material block 20 may be fabricated from any flexible material. In some embodiments, flexible material block 20 is fabricated from a foam or elastomer. In still further embodiments, flexible material block 20 is fabricated from synthetic or neoprene rubber, natural rubber, polyurethane, polystyrene, and the like. As used herein, “flexible” means that the material block may be compressed. Such compression is desirable, as will be described below, when the cooling device 10 is being utilized.

Graphite layer 30 may be wrapped around flexible material block 20. Graphite layer 30 may be attached to flexible material block 20 with any suitable fastening means such as one or more adhesives 40. For example, in one embodiment, the graphite layer 30 is attached to the flexible material block 20 with a pressure sensitive adhesive. In some embodiments, the pressure sensitive adhesive is a pressure sensitive acrylic adhesive. As shown in FIG. 1, the top and bottom surfaces of the flexible material block 20 have PSA layers to improve the contact with the heat source and heat sink surfaces. In some embodiments, the flexible material block 20 may simply be surrounded by the graphite layer 30 without a fastening means.

Graphite layer 30 is preferably a thin sheet, as shown; however, graphite layer 30 may take any form suitable to remove heat from a heat source. In alternate embodiments, a layer of carbon nanotubes may be used instead of graphite layer 30. The application of carbon nanotubes in layer form is known to those skilled in the art, and may include submersing flexible material block 20 in a nanotube solution and allowing the solution to dry.

In some embodiments, graphite layer 30 has a thickness on the order of 25-100 microns.

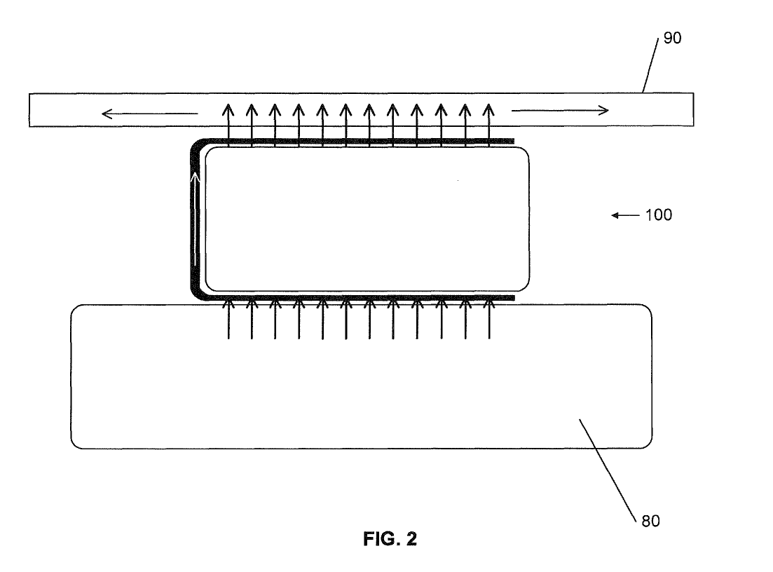

Turning now to FIG. 2, an example of the cooling device 10 placed proximate to a heat generating component 80 is shown. Here the cooling device 10 is sandwiched between the heat generating component or heat source 80 and a heat sink 90. In some embodiments, the cooling device 10 is held in place between the heat source 80 and heat sink 90 using compression. In other embodiments, the cooling device 10 may be fastened to the heat source 80 and/or heat sink 90.

As discussed above, the flexible material block 20 may be compressed such that the graphite layer 30 is pressed against the heat source 80 and heat sink 90 with sufficient force to ensure efficient transfer of heat between them and graphite layer 30.

In a preferred embodiment, the flexible material block 20 is compressed such that the graphite layer 20 can conform to the irregularities of the surfaces of the heat source 80 and heat sink 90, thereby maximizing the contact between the graphite layer 30 and the heat source 80 and heat sink 90.

In some embodiments, a softer or more flexible material may be used for flexible material block 20 in situations where more compression is desired. In cases where the compression is limited by the physical distance between two surfaces (e.g., of heat source 80 and heat sink 90), the use of a more flexible material block 20 may aid in ensuring that cooling device 10 conforms to the space constraints.

Because the cooling device 10 is secured in place using compression, it should be appreciated that the thickness of the flexible material block 20 is such as to fill the void between the heat source 80 and heat sink 90. Thereafter, the addition of the graphite layer 30, ensures that the cooling device 10 will be under compression. In one embodiment, the thickness of the flexible material block is on the order of 1-20 millimeters. As is appreciated, the physical distance between the heat source 80 and heat sink 90 generally sets the thickness requirement for cooling device 10.

As shown in FIG. 2, the heat is transferred from the heat source 80 to the cooling device 10, as indicated by arrows. The heat is then transferred from the cooling device 10 to the heat sink 90, as indicated by arrows. In some embodiments, the graphite layer 30 has a high thermal conductivity. For example, in an embodiment, the thermal conductivity of graphite layer 30 is on the order of 1000 W/mK.

In a preferred embodiment, the majority of the heat is transferred from the heat source 80 to the heat sink 90, via graphite layer 30. For example, in such an embodiment, the flexible material block 20 is constructed from an insulation material (e.g., is an insulator). Flexible material block 20 may include a thermally conductive material, to increase overall thermal conductivity in cooling device 10.

In other embodiments, a majority of the heat is transferred via flexible material block 20. As such, flexible material block 20 may be constructed as an insulator or conductor, provided it meets the requirement of compressibility.

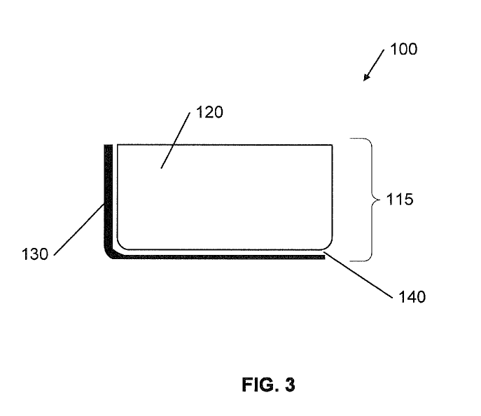

Turning now to FIG. 3, an alternate cooling device 100 is shown. Cooling device 100 includes a device body 115 which is formed from a flexible material block 120. As shown in FIG. 3, a graphite layer 130 is attached to flexible material block 120 on two sides.

The device 100 of FIG. 3 differs from the device 10 of FIG. 1, in that the graphite layer is not wrapped around the three surfaces of the flexible block. Similar to FIG. 1, graphite layer 130 may be attached to flexible material block 120 using an adhesive 140 such as PSA. PSA layers can be provided on the outer surfaces also, if it is desired.

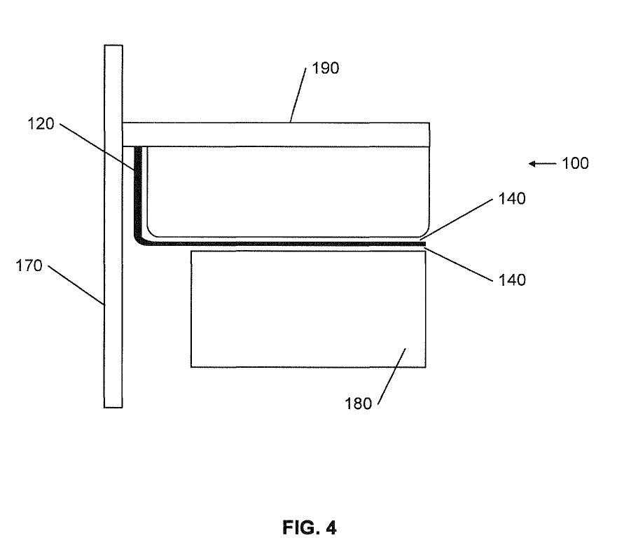

Turning now to FIG. 4, an example of the cooling device 100 placed proximate to a heat generating component 180 and heat sink 170 is shown. Here the heat generating component 180 and heat sink 170 are not parallel to each other, but rather perpendicular to each other. Also shown in contact with the cooling device 100 is a lid 190. Lid 190 aids in compressing the flexible material block 120 and applying pressure on graphite layer 130 so that contact between the cooling device 100 and heat generating component 180 ensures adequate heat transfer.

In some embodiments, the cooling device 100 is held in place between the heat source 180 and lid 190 using compression. In other embodiments, the cooling device 100 may be fastened to the heat source 180 and/or heat sink 170 and/or lid 190.

As shown in FIG. 4, because the cooling device 100 is not held under compression between the heat source 180 and heat sink 170, another method is desired to ensure compression of the cooling device 100 in one or both directions normal to the heat source 180 and heat sink 170 surfaces. For example, another supporting material having two surfaces one parallel to the heat source 180 and the other parallel to the heat sink 170 may be used to hold the cooling device 100 under compression. In such cases, the shape of the cooling device 100 may be altered or bent to conform to using the supporting material.

As is easily appreciated, there are numerous applications for surfaces that are placed at arbitrary angles to each other, in which the cooling devices 10, 100 could aid in heat removal. The areas of application can be as varied as using casings as heat sinks, thus avoiding or reducing expensive heat sinks and fans.

Benefits associated with the cooling devices described herein include ease of installation, repair, low cost and reliable contact. The present cooling devices provide an effective, convenient and manufacturable solution for dissipating heat from heat generating devices to heat spreading surfaces in places where they are not physically located close enough to ensure proper heat dissipation (e.g., conventional methods).

As stated above, the height or thickness of the cooling device 10, 100 can be decided based on the gap between the two surfaces to be connected thermally. This is possible since the conduction is generally not through the thickness of the flexible material block, but rather through the graphite layer. As will also be appreciated, the cooling device 10, 100 can be designed for different shapes to suit different applications, where the heat source and heat sink surfaces are not flat, parallel surfaces.

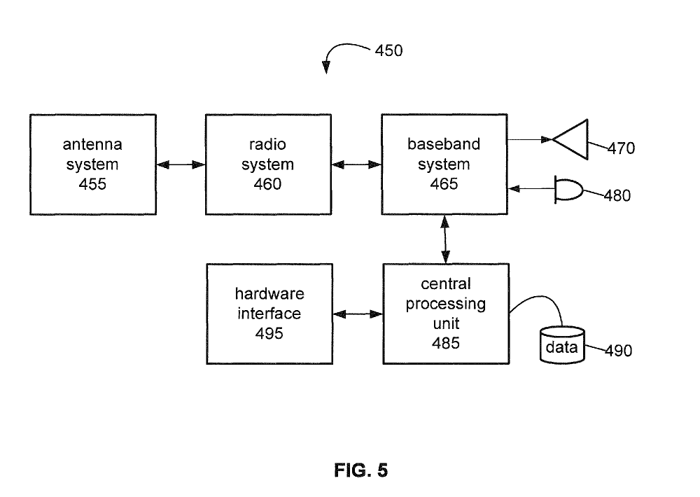

FIG. 5 is a block diagram illustrating an example wireless communication device 450 that may be used in connection with various embodiments described herein. In the illustrated embodiment, wireless communication device 450 comprises an antenna system 455, a radio system 460, a baseband system 465, a speaker 464, a microphone 470, a central processing unit (“CPU”) 485, a data storage area 490, and a hardware interface 495. As is appreciated, CPU 485 may generate sufficient heat to warrant use of a cooling device, described above. In the wireless communication device 450, radio frequency (“RF”) signals are transmitted and received over the air by the antenna system 455 under the management of the radio system 460.

In one embodiment, the antenna system 455 may comprise one or more antennae and one or more multiplexors (not shown) that perform a switching function to provide the antenna system 455 with transmit and receive signal paths. In the receive path, received RF signals can be coupled from a multiplexor to a low noise amplifier (not shown) that amplifies the received RF signal and sends the amplified signal to the radio system 460.

In alternative embodiments, the radio system 460 may comprise one or more radios that are configured to communication over various frequencies. In one embodiment, the radio system 460 may combine a demodulator (not shown) and modulator (not shown) in one integrated circuit (“IC”). The demodulator and modulator can also be separate components. In the incoming path, the demodulator strips away the RF carrier signal leaving a baseband receive audio signal, which is sent from the radio system 460 to the baseband system 465.

If the received signal contains audio information, then baseband system 465 decodes the signal and converts it to an analog signal. Then the signal is amplified and sent to the speaker 470. The baseband system 465 also receives analog audio signals from the microphone 480. These analog audio signals are converted to digital signals and encoded by the baseband system 465. The baseband system 465 also codes the digital signals for transmission and generates a baseband transmit audio signal that is routed to the modulator portion of the radio system 460. The modulator mixes the baseband transmit audio signal with an RF carrier signal generating an RF transmit signal that is routed to the antenna system and may pass through a power amplifier (not shown). The power amplifier amplifies the RF transmit signal and routes it to the antenna system 455 where the signal is switched to the antenna port for transmission.

The baseband system 465 is also communicatively coupled with the central processing unit 485. The central processing unit 485 has access to a data storage area 490. The central processing unit 485 is preferably configured to execute instructions (i.e., computer programs or software) that can be stored in the data storage area 490. Computer programs can also be received from the baseband processor 465 and stored in the data storage area 490 or executed upon receipt. Such computer programs, when executed, enable the wireless communication device 450 to perform the various functions of the present invention as previously described. For example, data storage area 490 may include various software modules (not shown).

In this description, the term “computer readable medium” is used to refer to any media used to provide executable instructions (e.g., software and computer programs) to the wireless communication device 450 for execution by the central processing unit 485. Examples of these media include the data storage area 490, microphone 470 (via the baseband system 465), antenna system 455 (also via the baseband system 465), and hardware interface 495. These computer readable mediums are means for providing executable code, programming instructions, and software to the wireless communication device 450. The executable code, programming instructions, and software, when executed by the central processing unit 485, preferably cause the central processing unit 485 to perform the inventive features and functions previously described herein.

The central processing unit 485 is also preferably configured to receive notifications from the hardware interface 495 when new devices are detected by the hardware interface. Hardware interface 495 can be a combination electromechanical detector with controlling software that communicates with the CPU 485 and interacts with new devices. The hardware interface 495 may be a firewire port, a USB port, a Bluetooth or infrared wireless unit, or any of a variety of wired or wireless access mechanisms. Examples of hardware that may be linked with the device 450 include data storage devices, computing devices, headphones, microphones, and the like.

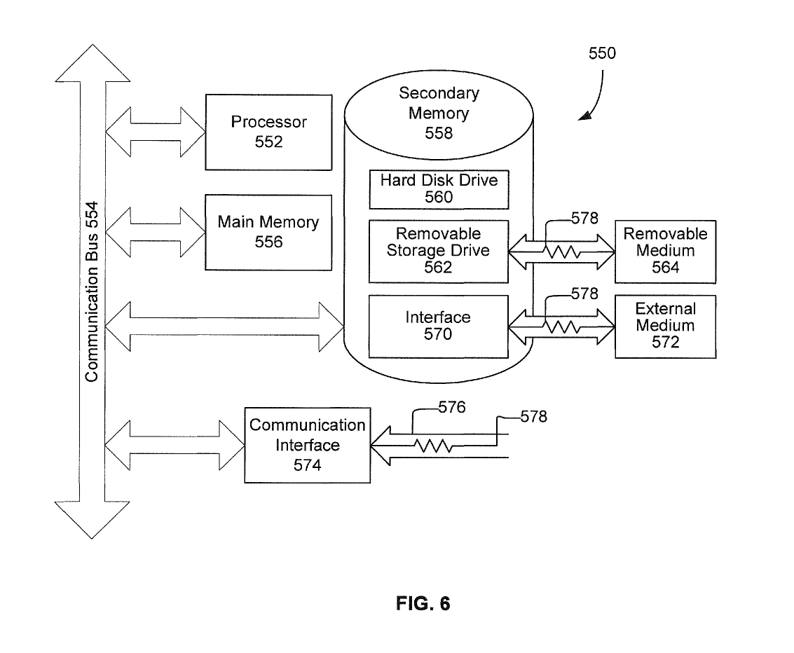

FIG. 6 is a block diagram illustrating an example computer system 550 that may be used in connection with various embodiments described herein. The computer system 550 preferably includes one or more processors, such as processor 552. Additional processors may be provided, such as an auxiliary processor to manage input/output, an auxiliary processor to perform floating point mathematical operations, a special-purpose microprocessor having an architecture suitable for fast execution of signal processing algorithms (e.g., digital signal processor), a slave processor subordinate to the main processing system (e.g., back-end processor), an additional microprocessor or controller for dual or multiple processor systems, or a coprocessor. Such auxiliary processors may be discrete processors or may be integrated with the processor 552. As is appreciated, each processor 552 may generate sufficient heat to warrant use of a cooling device, as described above.

The processor 552 is preferably connected to a communication bus 554. The communication bus 554 may include a data channel for facilitating information transfer between storage and other peripheral components of the computer system 550. The communication bus 554 further may provide a set of signals used for communication with the processor 552, including a data bus, address bus, and control bus (not shown). The communication bus 554 may comprise any standard or non-standard bus architecture such as, for example, bus architectures compliant with industry standard architecture (“ISA”), extended industry standard architecture (“EISA”), Micro Channel Architecture (“MCA”), peripheral component interconnect (“PCI”) local bus, or standards promulgated by the Institute of Electrical and Electronics Engineers (“IEEE”) including IEEE 488 general-purpose interface bus (“GPIB”), IEEE 696/S-100, and the like.

Computer system 550 preferably includes a main memory 556 and may also include a secondary memory 558. The main memory 556 provides storage of instructions and data for programs executing on the processor 552. The main memory 556 is typically semiconductor-based memory such as dynamic random access memory (“DRAM”) and/or static random access memory (“SRAM”). Other semiconductor-based memory types include, for example, synchronous dynamic random access memory (“SDRAM”), Rambus dynamic random access memory (“RDRAM”), ferroelectric random access memory (“FRAM”), and the like, including read only memory (“ROM”).

The secondary memory 558 may optionally include a hard disk drive 560 and/or a removable storage drive 562, for example a floppy disk drive, a magnetic tape drive, a compact disc (“CD”) drive, a digital versatile disc (“DVD”) drive, etc. The removable storage drive 562 reads from and/or writes to a removable storage medium 564 in a well-known manner. Removable storage medium 564 may be, for example, a floppy disk, magnetic tape, CD, DVD, etc.

The removable storage medium 564 is preferably a computer readable medium having stored thereon computer executable code (i.e., software) and/or data. The computer software or data stored on the removable storage medium 564 is read into the computer system 550 as electrical communication signals 578.

In alternative embodiments, secondary memory 558 may include other similar means for allowing computer programs or other data or instructions to be loaded into the computer system 550. Such means may include, for example, an external storage medium 572 and an interface 570. Examples of external storage medium 572 may include an external hard disk drive or an external optical drive, or and external magneto-optical drive.

Other examples of secondary memory 558 may include semiconductor-based memory such as programmable read-only memory (“PROM”), erasable programmable read-only memory (“EPROM”), electrically erasable read-only memory (“EEPROM”), or flash memory (block oriented memory similar to EEPROM). Also included are any other removable storage units 572 and interfaces 570, which allow software and data to be transferred from the removable storage unit 572 to the computer system 550.

Computer system 550 may also include a communication interface 574. The communication interface 574 allows software and data to be transferred between computer system 550 and external devices (e.g. printers), networks, or information sources. For example, computer software or executable code may be transferred to computer system 550 from a network server via communication interface 574. Examples of communication interface 574 include a modem, a network interface card (“NIC”), a communications port, a PCMCIA slot and card, an infrared interface, and an IEEE 1394 fire-wire, just to name a few.

Communication interface 574 preferably implements industry promulgated protocol standards, such as Ethernet IEEE 802 standards, Fiber Channel, digital subscriber line (“DSL”), asynchronous digital subscriber line (“ADSL”), frame relay, asynchronous transfer mode (“ATM”), integrated digital services network (“ISDN”), personal communications services (“PCS”), transmission control protocol/Internet protocol (“TCP/IP”), serial line Internet protocol/point to point protocol (“SLIP/PPP”), and so on, but may also implement customized or non-standard interface protocols as well.

Software and data transferred via communication interface 574 are generally in the form of electrical communication signals 578. These signals 578 are preferably provided to communication interface 574 via a communication channel 576. Communication channel 576 carries signals 578 and can be implemented using a variety of wired or wireless communication means including wire or cable, fiber optics, conventional phone line, cellular phone link, wireless data communication link, radio frequency (RF) link, or infrared link, just to name a few.

Computer executable code (i.e., computer programs or software) is stored in the main memory 556 and/or the secondary memory 558. Computer programs can also be received via communication interface 574 and stored in the main memory 556 and/or the secondary memory 558. Such computer programs, when executed, enable the computer system 550 to perform the various functions of the present invention as previously described.

In this description, the term “computer readable medium” is used to refer to any media used to provide computer executable code (e.g., software and computer programs) to the computer system 550. Examples of these media include main memory 556, secondary memory 558 (including hard disk drive 560, removable storage medium 564, and external storage medium 572), and any peripheral device communicatively coupled with communication interface 574 (including a network information server or other network device). These computer readable mediums are means for providing executable code, programming instructions, and software to the computer system 550.

In an embodiment that is implemented using software, the software may be stored on a computer readable medium and loaded into computer system 550 by way of removable storage drive 562, interface 570, or communication interface 574. In such an embodiment, the software is loaded into the computer system 550 in the form of electrical communication signals 578. The software, when executed by the processor 552, preferably causes the processor 552 to perform the inventive features and functions previously described herein.

Various embodiments may also be implemented primarily in hardware using, for example, components such as application specific integrated circuits (“ASICs”), or field programmable gate arrays (“FPGAs”). Implementation of a hardware state machine capable of performing the functions described herein will also be apparent to those skilled in the relevant art. Various embodiments may also be implemented using a combination of both hardware and software.

Furthermore, those of skill in the art will appreciate that the various illustrative logical blocks, modules, circuits, and method steps described in connection with the above described figures and the embodiments disclosed herein can often be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled persons can implement the described functionality in varying ways for each particular application, but such implementation decisions should not be interpreted as causing a departure from the scope of the invention. In addition, the grouping of functions within a module, block, circuit or step is for ease of description. Specific functions or steps can be moved from one module, block or circuit to another without departing from the invention.

Moreover, the various illustrative logical blocks, modules, and methods described in connection with the embodiments disclosed herein can be implemented or performed with a general purpose processor, a digital signal processor (“DSP”), an ASIC, FPGA or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration.

Additionally, the steps of a method or algorithm described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of storage medium including a network storage medium. An exemplary storage medium can be coupled to the processor such the processor can read information from, and write information to, the storage medium. In the alternative, the storage medium can be integral to the processor. The processor and the storage medium can also reside in an ASIC.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. For example, use with an electronic device is described as an embodiment, but that the invention can dissipate heat in other scenarios, e.g., if humanity wanted to cool the sun. Thus, it is to be understood that the description and drawings presented herein represent a presently preferred embodiment of the invention and are therefore representative of the subject matter which is broadly contemplated by the present invention. It is further understood that the scope of the present invention fully encompasses other embodiments that may become obvious to those skilled in the art and that the scope of the present invention is accordingly limited by nothing other than the appended claims.

1. A cooling device comprising:
a cooling device body comprising a flexible elastomer core surrounded on at least two sides by thermally conductive graphite.

2. The cooling device of claim 1, wherein the thermally conductive graphite comprises a graphite sheet having a thickness of approximately 0.025 to approximately 0.1 millimeters.

3. The cooling device of claim 1, wherein the flexible elastomeric core comprises a material selected from the group consisting of natural rubber, synthetic rubber, polyurethane, polystyrene, and combinations thereof.

4. The cooling device of claim 1, wherein the graphite has a thermal conductivity of approximately 1000 W/mK.

5. The cooling device of claim 1, wherein the flexible elastomeric core has a thickness of approximately 1 to approximately 20 millimeters.

6. The cooling device of claim 1, further comprising an adhesive layer in between at least a portion of the flexible elastomeric core and the thermally conductive graphite.

7. The cooling device of claim 6, wherein the adhesive layer comprises a pressure sensitive acrylic adhesive.

8. The cooling device of claim 1, wherein the flexible elastomeric core is capable of compression.

9. A method for cooling an electronic component comprising:
bringing a cooling device into thermal communication with the electronic component, wherein the cooling device comprises a flexible elastomer core surrounded on at least two sides by thermally conductive graphite.

10. The method of claim 9, wherein the cooling device is placed proximate to the electronic component and a thermal dissipation device.

11. The method of claim 10, wherein the cooling device is placed in between the electronic component and thermal dissipation device.

12. The method of claim 11, wherein the cooling device is secured in between the electronic component and thermal dissipation device by compression of the cooling device.

13. The method of claim 10, wherein the thermal dissipation device is a heat sink.

14. The method of claim 9, wherein the cooling device further comprises an adhesive layer in between at least a portion of the flexible elastomeric core and the thermally conductive graphite.

15. The method of claim 9, wherein the thermally conductive graphite surrounds the flexible elastomeric core on three sides.

16. The method of claim 9, wherein the electronic component is selected from the group consisting of a general purpose processor, a digital signal processor (“DSP”), an application specific integrated circuits (“ASIC”), and a field programmable gate array (“FPGA”).

17. The method of claim 9, wherein the electronic component is a processor.

18. A heat sink comprising:
a cooling device comprising a cooling device body comprising a foam core surrounded on at least two sides by thermally conductive graphite.

19. The heat sink of claim 16, further comprising an additional thermal dissipation device in thermal communication with the heat sink.

20. The heat sink of claim 16, wherein the cooling device has a length and width that is similar to the length and width of an electronic component to be cooled.
